(19) United States
(12) Patent Application Publication
(10) Pub. No.: US 2026/0144026 A1
(43) Pub. Date: May 21, 2026

(54) SURFACE INHIBITION TO REDUCE BOTTOM UP OXIDE DEPOSITION IN VERTICAL TRENCH

(71) Applicant: Applied Materials, Inc., Santa Clara, CA (US)

(72) Inventors: Vennila Sigamani SANKGEETH, San Jose, CA (US); Jain AKSHAT, IN (SG); Yu-Wei WU, San Jose, CA (US); Mandar B. PANDIT, San Jose, CA (US); Praket Prakash JHA, San Jose, CA (US); Jingmei LIANG, San Jose, CA (US)

(21) Appl. No.: 18/949,523

(22) Filed: Nov. 15, 2024

(51) Int. Cl. H01L 21/762; H01L 21/02

(52) U.S. Cl. CPC H10W 10/014; H10P 14/6509; H10P 14/6686; H10W 10/17

(57) ABSTRACT

Embodiments of the disclosure generally relate to methods for filling substrate features. Particularly, embodiments of the disclosure are directed to methods improving lateral gap fill. In one embodiment, a method includes positioning a substrate having a feature formed therein within a processing chamber, the feature comprising a vertical trench and one or more lateral trenches extending from the vertical trench; exposing the substrate to at least one pretreatment precursor to pretreat the substrate, wherein pretreating the substrate increases a hydrophobicity of one or more surfaces of the feature in the substrate; and depositing a gapfill material on the substrate and the feature formed therein to gapfill the vertical trench and the one or more lateral trenches of the feature.

### BACKGROUND

### Field

Embodiments of the disclosure generally relate to methods for filling substrate features. Particularly, embodiments of the disclosure are directed to methods improving lateral gap fill.

### Description of the Related Art

The transistor is a key component of most integrated circuits. Since the drive current, and therefore speed, of a transistor is proportional to the gate width of the transistor, faster transistors generally require larger gate width. Thus, there is a trade-off between transistor size and speed, and “fin” field-effect transistors (finFETs) have been developed to address the conflicting goals of a transistor having maximum drive current and minimum size. FinFETs are characterized by a fin-shaped channel region that greatly increases the size of the transistor without significantly increasing the footprint of the transistor and are now being applied in many integrated circuits. However, finFETs have their own drawbacks.

As the feature sizes of transistor devices continue to shrink to achieve greater circuit density and higher performance, there is a need to improve transistor device structure to improve electrostatic coupling and reduce negative effects such as parasitic capacitance and off-state leakage. Examples of transistor device structures include a planar structure, a fin field effect transistor (FinFET) structure, and a horizontal gate all around (hGAA) structure. The hGAA device structure includes several lattice matched channels suspended in a stacked configuration and connected by source/drain regions. The hGAA structure provides good electrostatic control and can find broad adoption in complementary metal oxide semiconductor (CMOS) wafer manufacturing.

However, as circuits are scaled to smaller dimensions and thus a smaller area, the required lateral spacing between adjacent lattice matched channels (e.g., nanosheets) suspended in the stacked configuration are very small to enable the vertical finFET devices to operate properly. Current deposition tools using isotropic deposition can create issues in applications of lateral fill, which in turn effects electrical performance, structural stability, and thermal management of the transistor.

Therefore, there is a need in the art for an improved method of filling lateral gaps between nanosheets of transistor device structures.

### SUMMARY

Embodiments of the disclosure generally relate to methods for filling substrate features. Particularly, embodiments of the disclosure are directed to methods improving lateral gap fill. In one embodiment, a method includes positioning a substrate having a feature formed therein within a processing chamber, the feature comprising a vertical trench and one or more lateral trenches extending from the vertical trench; exposing the substrate to at least one pretreatment precursor to pretreat the substrate, wherein pretreating the substrate increases a hydrophobicity of one or more surfaces of the feature in the substrate; and depositing a gapfill material on the substrate and the feature formed therein to gapfill the vertical trench and the one or more lateral trenches of the feature.

In another embodiment, a substrate processing method includes pretreating a substrate containing silicon, wherein the pretreating includes exposing the substrate to at least one pretreatment precursor and a UV light, wherein the at least one pretreatment precursor is one or more of: a hydrocarbon compound, Tetramethyldisiloxane (TMDS), Dimethylamino Trimethylsilane (DMATMS), and a chemical compound having a general structure

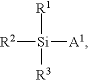

or combinations thereof, wherein R¹, R², and R³ are hydrocarbon functional groups each with a general formula of CₓH_{y} in which x has a range of between 1 and 8 and y has a range of between 1 and 17 and A¹ is a hydrogen atom, chlorine atom, bromine atom, iodine atom, or an amine group; and exposing the substrate to ozone (O₃) after the exposing the substrate to the at least one pretreatment precursor an the UV light, wherein a first surface of the substrate comprises a water contact angle greater than a second surface of the substrate.

In yet another embodiment, a non-transitory computer readable medium including instructions, that, when executed by a controller of a processing chamber, causes the processing chamber to perform operations includes positioning a substrate within a processing chamber; exposing the substrate to at least one pretreatment precursor to pretreat the substrate, wherein a pretreatment precursor is one or more of: a hydrocarbon compound, Tetramethyldisiloxane (TMDS), Dimethylamino Trimethylsilane (DMATMS), a chemical compound having a general structure:

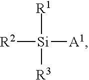

or combinations thereof, wherein R1, R2, and R3 are hydrocarbon functional groups each with a general formula of CₓH_{y} in which x has a range of between 1 and 8 and y has a range of between 1 and 17 and A¹ is a hydrogen atom, chlorine atom, bromine atom, iodine atom, or an amine group; and curing the substrate, a first surface of the substrate having a water contact angle greater than a second surface of the substrate.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1A is a schematic cross-sectional view of trenches having hydrophilic and hydrophobic lateral and vertical surfaces, according to one or more embodiments.

FIG. 1B is a graph illustrating the water contact angle of various trenches having different surface pretreatments, according to one or more embodiments.

FIG. 2 illustrates a flow chart for a method of substrate pretreating, according to one or more embodiments.

FIGS. 3A-3E are images depicting cross-sectional views of trenches having various pretreatment processes, according to one or more embodiments.

FIG. 4 is a schematic cross-sectional view of a trench, according to one or more embodiments.

FIG. 5 illustrates a cluster tool, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the disclosure generally relate to methods for filling substrate features. Particularly, embodiments of the disclosure are directed to methods improving lateral gap fill. In one embodiment, a method includes positioning a substrate having a feature formed therein within a processing chamber, the feature comprising a vertical trench and one or more lateral trenches extending from the vertical trench; exposing the substrate to at least one pretreatment precursor to pretreat the substrate, wherein pretreating the substrate increases a hydrophobicity of one or more surfaces of the feature in the substrate; and depositing a gapfill material on the substrate and the feature formed therein to gapfill the vertical trench and the one or more lateral trenches of the feature.

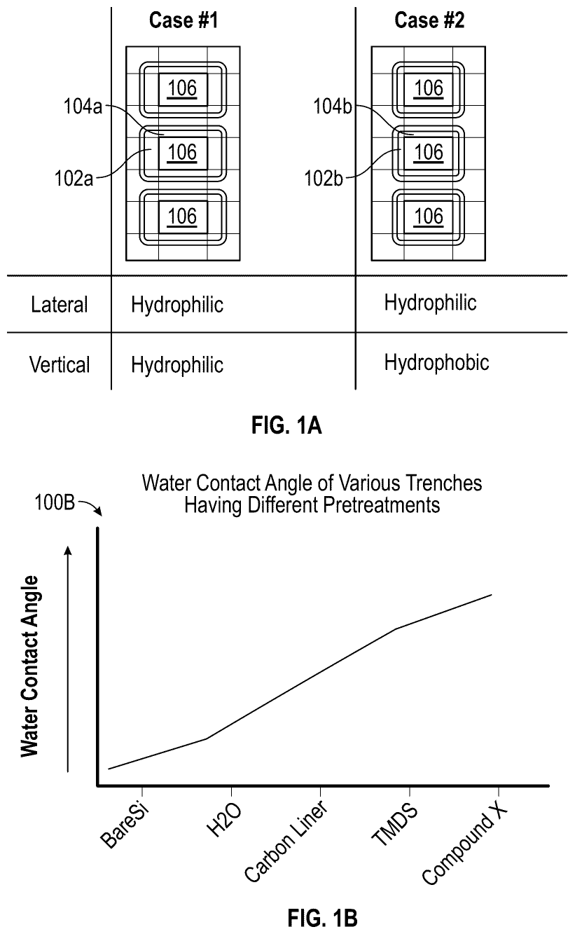

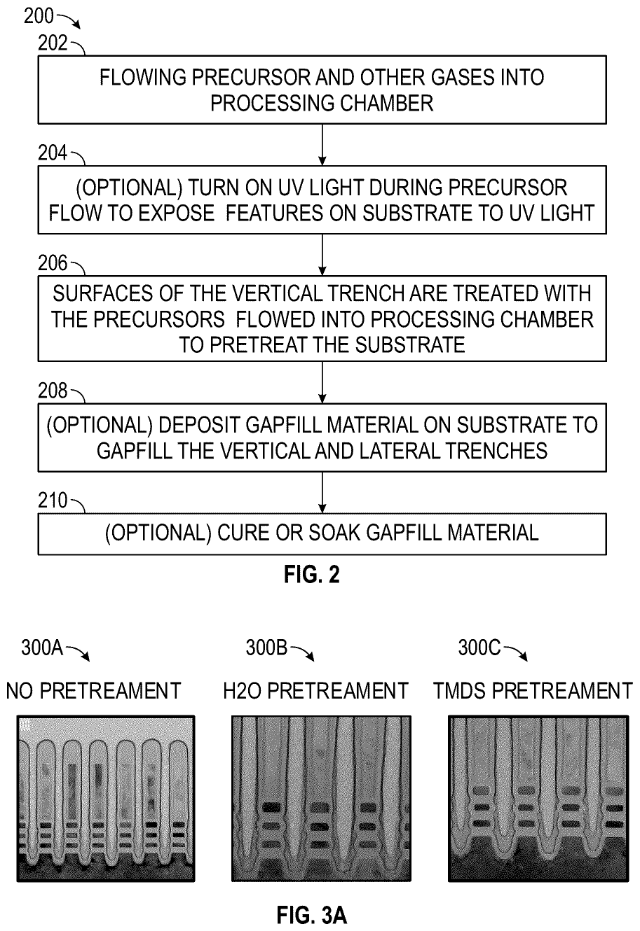

FIG. 1A is a schematic cross-sectional view of trenches having hydrophilic and hydrophobic lateral and vertical surfaces, according to one or more embodiments. In case #1, a lateral surface 104a of a lateral trench in a substrate (e.g., a nanosheet 106) and a vertical surface 102a of a vertical trench adjacent the nanosheet 106 are hydrophilic. Whereas, in case #2, a lateral surface 104b of the lateral trench between the nanosheets 106 is hydrophilic, while the vertical surface 102b of the vertical trench adjacent each of the nanosheet 106 is hydrophobic. By rendering vertical trench surfaces (e.g., sidewall surfaces and bottom surface of the vertical trench) more hydrophobic, bottom deposition of the trench may be reduced because the surface energy of the hydrophobic surfaces is changed, which in turn changes the wetting behavior, nucleation, and film growth of the hydrophobic surfaces. As a result, it was observed that hydrophobic vertical surfaces in a vertical trench during gapfill can improve the filling of adjacent lateral trenches extending therefrom.

As shown in FIG. 1A, the lateral surface 104b is hydrophilic and the vertical surface 102b is hydrophobic. The hydrophobic vertical surface 102b is pretreated using one or more of: a hydrocarbon compound, Tetramethyldisiloxane (TMDS), Dimethylamino Trimethylsilane (DMATMS), and a chemical compound (“Compound X”) having a general structure

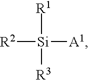

wherein R¹, R², and R³ are hydrocarbon functional groups each with a general formula CₓH_{y} in which x has a range of between 1 and 8 and y has a range of between 1 and 17. The hydrocarbon functional group can be alkyl, alkene, alkyne group with straight chain/branched chain/cyclic. A¹ is a hydrogen atom, chlorine atom, bromine atom, iodine atom, or an amine group. The amine group can be primary (with one R and one H connected to Nitrogen: RNH—) or secondary (with two R connected to Nitrogen: R₂N—).

FIG. 1B is a graph 100B illustrating the water contact angles of various trenches having different surface pretreatments, according to one or more embodiments. Graph 100B depicts the water contact angle of various trenches pretreated with different substrates, including one or more of a hydrocarbon compound, Tetramethyldisiloxane (TMDS), and chemical compound (“Compound X”). The order of hydrophobicity of each substrate from highest to lowest is Compound X, TMDS, a carbon liner (e.g., a carbon containing substrate), H₂O, and then bare silicon.

Without being bound by theory, it is believed that by pretreating the vertical surfaces of a vertical trench to make the vertical surfaces hydrophobic prior to depositing a film (e.g., a thermal oxide film) on the substrate surface, a thickness of the film deposited on the vertical surfaces in the later trenches can be minimized. As compared to conventional deposition techniques such as chemical vapor deposition (CVD) or atomic layer deposition (ALD), a thickness of the film deposited in the vertical trench may disrupt deposition in lateral trenches extending therefrom. Accordingly, advantageous of the present disclosure provide for using a pretreatment to help with ensuring lateral deposition in such lateral trenches, even in complex structures. For example, as further discussed below, the addition of a pretreatment operation to make the vertical surfaces hydrophobic before depositing gapfill material, such as an oxide film, on the substrate can reduce bottom up deposition in narrow finFET structures and allow for improved lateral trenches gapfill.

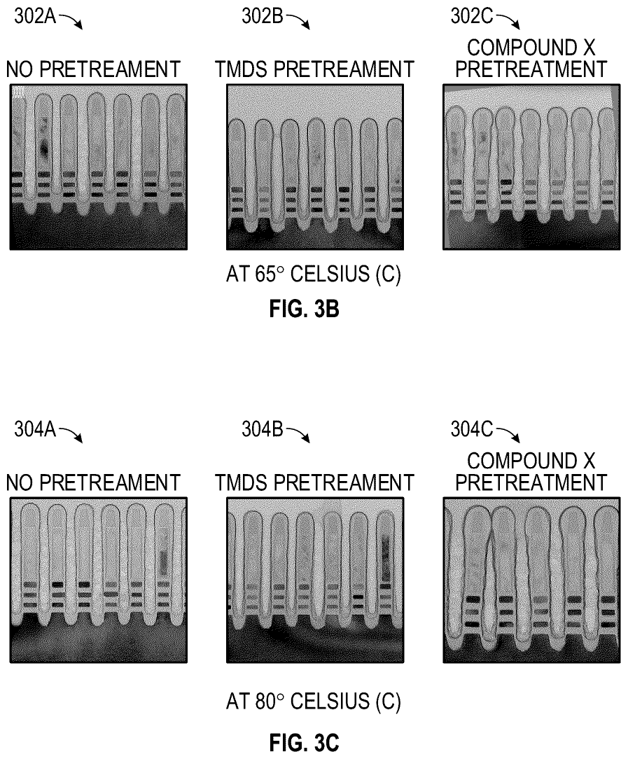

FIG. 2 illustrates an exemplary method 200 of substrate pretreating, according to one or more embodiments. Method 200 begins at operation 202 in which a substrate (e.g., a nanosheet or interconnect structure) is transferred into a processing chamber. In some embodiments, which may be combined with other embodiments, the processing chamber may be a deposition chamber, configured to deposit materials onto a substrate using a vapor deposition process (thermal or plasma enhanced), such as atomic layer deposition (ALD), plasma enhanced ALD (PEALD), chemical vapor deposition (CVD), or plasma enhanced chemical vapor deposition (PECVD). In some embodiments, the processing chamber may be a UV-based processing chamber for pretreating surfaces of a substrate using a UV assisted deposition process.

At operation 202, the substrate is processed in a processing chamber to pretreat the substrate. Operation 202 may include flowing a pretreatment precursor and carrier gases or combinations thereof into the processing chamber to treat the substrate. The substrate may include one or more vertical trenches having one or more lateral trenches extending therefrom. Operation 202 may be performed to pretreat surfaces of the vertical trench and increase the hydrophobicity of the surfaces of the vertical trench.

The pretreatment precursor may include one or more of a hydrocarbon compound, Tetramethyldisiloxane (TMDs), Dimethylamino Trimethylsilane (DMATMS), and a chemical compound (“Compound X”) having a general structure

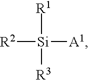

wherein R¹, R², and R³ are hydrocarbon functional groups each with a general formula CₓH_{y} in which x has a range of between 1 and 8 and y has a range of between 1 and 17. The hydrocarbon functional group can be alkyl, alkene, alkyne group with straight chain/branched chain/cyclic. A¹ is a hydrogen atom, chlorine atom, bromine atom, iodine atom, or an amine group. The amine group can be primary (with one R and one H connected to Nitrogen: RNH—) or secondary (with two R connected to Nitrogen: R₂N—). Examples of carrier gases include He, Ar, or combinations thereof.

The temperature of the processing chamber during operation 202 can be any suitable temperature depending on, for example, the precursor(s) being used. During processing, the substrate can be heated or cooled. Such heating or cooling can be accomplished by any suitable means. For example, the substrate is maintained at a temperature greater than or equal to about 25° C., or about 50° C., or about 100° C., or about 150° C., or about 200° C., or about 250° C., or about 300° C., or about 350° C., or about 400° C., or about 450° C., or about 500° C. In other examples, the substrate temperature is maintained at a temperature less than or equal to about 600° C., or about 550° C., or about 500° C., or about 450° C., or about 400° C., or about 350° C., or about 300° C., or about 250° C., or about 200° C., or about 150° C., or about 100° C., or about 50° C., or about 25° C. In yet another example, when exposing the substrate to the pretreatment precursor(s) a chamber temperature of the processing chamber is between 10° C. and 500° C., such as between 10° C. and 400° C., such as between 10° C. and 300° C., such as between 10° C. and 200° C.

In operation 202, the flow rate of the pretreatment precursor and carrier gases can be any suitable flow rate such as less than 7000 sccm, such as about 0.1 sccm to about 7000 sccm, such as about 2 sccm to about 5000 sccm, such as about 3 sccm to about 3000 sccm, such as about 5 sccm to about 2000 sccm. An example flow rate of the pretreatment precursor (e.g., Compound X) during operation 202 includes between about 100 sccm to about 2000 sccm. An example flow rate of a carrier gas (e.g., He) during operation 202 includes between about 500 sccm to about 5000 sccm.

The pretreatment precursor and carrier gases can be provided at any suitable pressure such as about 5 m Torr to about 25 Torr, such as about 100 mTorr to about 20 Torr, such as about 5 Torr to about 20 Torr, such as about 50 m Torr to about 2000 m Torr, such as about 100 mTorr to about 1000 mTorr, such as about 200 mTorr to about 500 mTorr.

The period of time that the substrate is exposed to pretreatment precursor and carrier gases at operation 202 may be any suitable amount of time necessary to allow for the deposition of a hydrophobic pretreatment of the substrate surface (e.g., surface of a vertical trench) to increase the hydrophobicity of the surface. The substrate may be exposed to the pretreatment precursor and carrier gases for less than 6 minutes, such as about 30 seconds to about 6 minutes, such as about 1 minute to 6 minutes, such as about 2 minutes to 6 minutes, such as about 3 minutes to 6 minutes, such as about 4 minutes to about 6 minutes.

In some embodiments, the carrier gas is an inert gas that may additionally be provided to the processing chamber at the same time as the pretreatment precursor and carrier gases. The inert gas may be flowed into the processing chamber at a constant flow rate of about 1 sccm to about 10000 sccm. The inert gas may be any inert gas, such as argon, helium, neon, combinations thereof, or the like.

In some embodiments, the processing chamber is maintained at a pressure of about 0.2 Torr to about 100 Torr throughout the UV-assisted deposition, such as about 0.3 Torr to about 90 Torr, such as about 0.5 Torr to about 80 Torr, such as about 1 Torr to about 50 Torr. The processing chamber pressure during deposition can be about 50 mTorr to 750 Torr, such as about 100 mTorr to about 400 Torr, such as about 1 Torr to about 100 Torr, such as about 2 Torr to about 10 Torr. A RF bias power at a frequency less than or equal to about 13 MHZ, such as 4.2 HZ, may be applied to maintain a plasma in the treatment gas mixture (e.g., a hydrogen containing gas). For example, a RF bias power of less than 1000 Watts, such as about 600 Watts may be applied to maintain a plasma inside the processing chamber.

Operation 202 may also be performed utilizing UV light during the flowing of the pretreatment precursor and other gases. For example, at optional operation 204 (which may occur concurrently with operation 202), the substrate may be exposed to UV light during operation 202 to perform a UV-assisted deposition process and deposit a pretreatment layer on a surface (e.g., a lateral or vertical surface) of the substrate, or to pretreat a surface of the substrate to increase the hydrophobicity of the surface of the substrate. The UV unit may be turned on while or after the flowing of the precursor into the UV-based processing chamber. In some embodiments, the uniformity of UV radiation exposure may be adjusted with spacing and rotating of the UV unit in the UV based processing chamber. In some embodiments, the power of a UV unit and UV lamp bulbs is about 12 kW. In some embodiments, the UV power output by the UV lamp bulbs for operation 202 and 204 may be from about 1% to about 100%, such as between about 50% and about 90%, such as between about 6% to about 80%. In some embodiments, the UV radiance of the UV unit in the UV based processing chamber is less than 400 Arbitrary units (a.u), such as between about 0 a.u and about 400 a.u, such as between about 50 a.u and about 350 a.u, such as between about 100 a.u and about 300 a.u, such as between about 150 a.u and about 250 a.u.

At operation 206, the surfaces of the vertical trench are treated with the gases from operation 202, including but not limited to pretreatment precursors and carrier gases, and, optionally, UV light, flowed into the processing chamber to pretreat the surfaces to become more hydrophobic.

After the pretreatment of the vertical trenches, optional operation 208 may be performed. At optional operation 208, the vertical and lateral trenches of the substrate are gapfilled with gapfill material. Depositing the gapfill material on the substrate comprises gapfilling the one or more lateral trenches of the feature prior to gapfilling the vertical trench. Examples of the vertical and lateral trenches being gapfilled include depositing a film (e.g., a thermal oxide film) over the substrate. During the deposition of the oxide film, processing gases and carrier gases are flowed into the processing chamber. Examples of processing gases include Trisilylamine (TSA), NH₃, and O₂, or combinations thereof. Examples of the carrier gases include He, Ar, or combinations thereof. Examples of the flow rate of processing gas TSA into the processing chamber during optional operation 208 includes between about 100 sccm to 1000 sccm. Examples of the flow rate of processing gas NH₃ into the processing chamber during optional operation 208 include less than 700 sccm, such between about 0.1 sccm to about 700 sccm. Examples of the flow rate of processing gas O₂ into the processing chamber during optional operation 208 include less than 500 sccm, such between about 0.1 sccm to about 500 sccm. Examples of the flow rate of carrier gas Ar into the processing chamber during optional operation 208 includes between about 1000 sccm to about 7000 sccm. Examples of the flow rate of carrier gas He into the processing chamber during optional operation 208 includes between about 500 sccm to about 5000 sccm. It is noted that each individual operation 202, 204, 206, 208, and 210 may be individually repeated a suitable number of times necessary to allow for the hydrophobic pretreatment of a surface (e.g., a lateral or vertical surface) of the substrate before proceeding to the next operation.

At optional operation 210, the deposited gapfill material of operation 208 is cured or soaked. Curing the deposited gapfill material deposited on the substrate improves the quality of the deposited gapfill material, and occurs by flowing one or more curing precursors (e.g., O₃) into the processing chamber at a temperature of less than 100° C., such as between about 20° C. and about 80° C., such as between about 40° C. and about 60° C., such as 50° C. Operation 208 may occur for a duration of less than 10 mins, such as between about 2 mins to about 8 mins, such as between about 4 mins to about 6 mins, such as about 6 mins. The processing chamber of operation 208 may be held at a pressure of less than 100 Torr, such as between about 20 Torr to about 80 Torr, such as about between about 40 Torr to about 60 Torr, such as 50 Torr.

A thickness of the hydrophobic surface of the substrate, or film disposed on the surface of the substrate, is less than 20 angstrom (Å), such as less than 10 Å. The water contact angle of the hydrophobic pretreated surface is greater than 70°, such as between 75° and 100°, such as greater than 90°, such as between 95° and 100°.

Increasing the hydrophobicity of vertical surfaces of a vertical trench provides for the minimization of trench bottom deposition of gapfill material before the gapfill of the lateral trenches is complete. Trench bottoms that are filled with gapfill material inhibit the filling of lateral trenches. Thus, by reducing trench bottom deposition rates, via minimization, and allowing lateral trenches to be filled completely before the trench bottoms are filled with gapfill material, higher quality and seamless gapfill in lateral trenches can be achieved. Thus, pretreating a substrate to make a vertical surface of the substrate hydrophobic prior to the deposition of a flowable film results in a reduced bottom thickness of a trench. Further, the pretreatment can act as a knob for a full deposition of a film (e.g., a thermal oxide film) on a lateral surface with minimal deposition on a vertical surface of the substrate. As a result, film thickness in a lateral trench can be controlled by minimizing oxide films in required directions (e.g., in a vertical trench), thus decreasing the impact on surrounding films/hardmasks.

### EXAMPLES

### Example 1

Samples were prepared in accordance to methods described herein, where a sample includes a trench where the vertical surfaces of the trench (e.g., sidewalls and bottom) are pretreated to be more hydrophobic than the lateral surfaces of the trench.

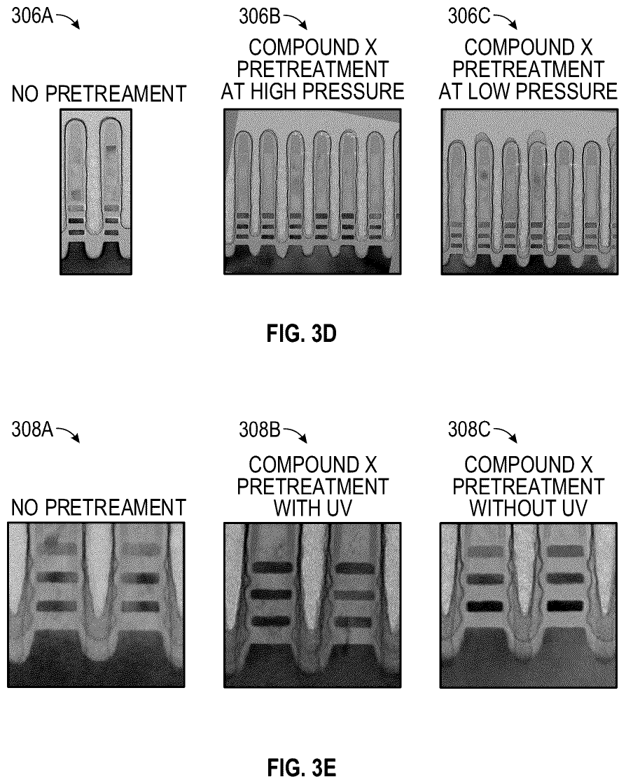

FIG. 3A are images depicting a cross-sectional view of trenches having various pretreatment processes, according to one or more embodiments. The vertical surfaces of trench 300A were not pretreated, yielding a water contact angle of 7′. The vertical surfaces of trench 300B were pretreated with H₂O, yielding a water contact angle of 22′. The vertical surfaces of trench 300C were pretreated with TMDS, yielding a water contact angle of 79′.

An exemplary process for pretreating the vertical surfaces of trench 300C with TDMS comprises a pretreatment operation (e.g., operations 202, 206 of FIG. 2), a deposition operation (e.g., operation 208 of FIG. 2), and an optional sequential treatment operation. The pretreatment step comprises flowing a pretreatment precursor (e.g., TMDS) and carrier gas(es) (e.g., He and/or Ar) into a processing chamber (e.g., an atomic layer deposition (ALD)) and exposing surfaces of the substrate to the pretreatment precursor and carrier gas(es) at a processing chamber temperature between 10° C. to 500° C. for a duration between 30 seconds and 6 minutes. The deposition operation comprises gapfilling the trenches with gapfill material (e.g., an oxide film), and flowing carrier gases (e.g., He and/or Ar) and processing gases (e.g., TSA, NH₃, and Ar) into the processing chamber (e.g., an atomic layer deposition (ALD)) containing the substrate at a chamber pressure of between about 1 Torr and 100 Torr, such as between about 20 Torr and about 80 Torr, such as between about 30 Torr and about 70 Torr, such as between about 40 Torr and about 60 Torr, such as about 50 Torr. The deposition operation is further conducted at a temperature less than 300° C., such as 250° C., for a duration less than 10 minutes, such as about 5 minutes. The optional sequential treatment operation comprises flowing additional carrier gases (e.g., He and/or Ar) and processing gases (e.g., TSA, NH₃, O₂, and/or H₂) into a processing chamber (e.g., a UV-based processing chamber) at a pressure of less than 1 Torr, such as 0.53 Torr, with a RF bias power at a frequency of less than or equal to 5 Hz at less than 1000 Watts, such as 600 Watts, at a UV power of about 6%.

TABLE 1
Summary of Different Treatments and Trench Surface Dimensions

| | | H20 | TMDS |
|---|---|---|---|
| | No Pretreatment | Pretreatment | Pretreatment |
| Treatment | (Trench 300A) | (Trench 300B) | (Trench 300C) |
| Water Contact | 7′ | 22′ | 79′ |
| Angle | | | |
| Bottom height (nm) | 7 | 11 | 5.1 |
| Sidewall (nm) | 4.4 | 4.4 | 4.7 |

As can be determined from analysis of Table 1, the greater water contact angle (i.e., increased hydrophobicity) of the vertical surfaces of trench 300C resulted in a lower bottom height (i.e., thinner trench bottom) while substantially maintaining the sidewall and dishing dimensions when compared to trenches 300A and 300B, which have lesser water contact angles. Thus, the pretreatment of the vertical surfaces of the trench to be more hydrophobic corresponds with an improved bottom thickness (i.e., a thinner trench bottom). While pretreating the vertical surfaces of a trench with H₂O results in a greater bottom thickness of the trench, because the vertical surfaces are more hydrophilic.

FIG. 3B are images depicting a cross-sectional view of trenches having various pretreatment processes at a lower temperature (65° C.), according to one or more embodiments. The vertical surfaces of trench 302A were not pretreated, yielding a water contact angle of 7′. The vertical surfaces of trench 302B were pretreated with TMDS, yielding a water contact angle of 79′. The vertical surfaces of trench 302C were pretreated with Compound X, yielding a water contact angle of 97′.

An exemplary process for pretreating the vertical surfaces of trench 302B with TDMS comprises a pretreatment operation (e.g., operations 202, 206 of FIG. 2), a deposition operation (e.g., operation 208 of FIG. 2), and an optional sequential treatment operation. The pretreatment step comprises flowing a pretreatment precursor (e.g., TMDS) and carrier gas(es) (e.g., He and/or Ar) into a processing chamber (e.g., an atomic layer deposition (ALD)) and exposing surfaces of the substrate to the pretreatment precursor and carrier gas(es) at a processing chamber temperature between 10° C. to 500° C. for a duration between 30 seconds and 6 minutes. The deposition operation comprises gapfilling the trenches with gapfill material (e.g., an oxide film), and flowing carrier gases (e.g., He and/or Ar) and processing gases (e.g., TSA, NH₃, and Ar) into the processing chamber (e.g., an atomic layer deposition (ALD)) containing the substrate at a chamber pressure of between about 1 Torr and 100 Torr, such as between about 20 Torr and about 80 Torr, such as between about 30 Torr and about 70 Torr, such as between about 40 Torr and about 60 Torr, such as about 50 Torr. The deposition operation is further conducted at a temperature less than 300° C., such as 250° C., for a duration less than 10 minutes, such as about 5 minutes. The optional sequential treatment operation comprising flowing additional carrier gases (e.g., He and/or Ar) and processing gases (e.g., TSA, NH₃, O₂, and/or H₂) into a processing chamber (e.g., a UV-based processing chamber) at a pressure of less than 1 Torr, such as 0.53 Torr, with a RF bias power at a frequency of less than or equal to 5 Hz at less than 1000 Watts, such as 600 Watts, at a UV power of about 6%.

An exemplary process for pretreating the vertical surfaces of trenches 302C with Compound X comprises a pretreatment operation (e.g., operations 202, 204, 206 of FIG. 2), a deposition operation (e.g., operation 208 of FIG. 2), and curing operation (e.g., operation 210 of FIG. 2). The pretreatment step comprises flowing a pretreatment precursor (e.g., Compound X) and carrier gas(es) (e.g., He and/or Ar) into a processing chamber (e.g., a UV-based processing chamber) and exposing surfaces of the substrate to the pretreatment precursor and carrier gas(es) at a processing chamber temperature between 10° C. to 500° C. for a duration between 30 seconds and 6 minutes. The deposition operation comprises gapfilling the trenches with gapfill material (e.g., an oxide film), and flowing carrier gas(es) (e.g., He and/or Ar) and processing gases (e.g., TSA, NH₃, O₂, and H₂) into a processing chamber (e.g., a UV-based processing chamber) containing the substrate at a pressure of less than 1 Torr, such as 0.5 Torr, and a temperature less than 100° C., such as 65° C., for a duration less than 1 minute. The curing operation comprises curing the deposited gapfill material and flowing a curing precursor (e.g., O₃) into the processing chamber at a temperature of less than 100° C., such as 50° C., for a duration of less than 10 mins, such as about 6 mins, at a pressure of less than 100 Torr, such as 50 Torr.

TABLE 2
Summary of Different Treatments and Trench
Surface Dimensions with Deposition at 65° C.

| | | TMDS | Compound X |
|---|---|---|---|
| | No Pretreatment | Pretreatment | Pretreatment |
| Treatment | (Trench 302A) | (Trench 302B) | (Trench 302C) |
| Water Contact | 7′ | 79′ | 97′ |
| Angle | | | |
| Bottom height (nm) | 25.4 | 16 | 13.2 |
| Sidewall (nm) | 2.7 | 3.1 | 1.5 |

FIG. 3C are images depicting a cross-sectional view of trenches having various pretreatment processes at a higher temperature (80° C.), according to one or more embodiments. The vertical surfaces of trench 304A were not pretreated, yielding a water contact angle of 7′. The vertical surfaces of trench 304B were pretreated with TMDS, yielding a water contact angle of 79′. The vertical surfaces of trench 304C were pretreated with Compound X, yielding a water contact angle of 97′.

An exemplary process for pretreating the vertical surfaces of trench 304C with Compound X comprises a pretreatment operation (e.g., operations 202, 206 of FIG. 2), a deposition operation (e.g., operation 208 of FIG. 2), and curing operation (e.g., operation 210 of FIG. 2). The pretreatment step comprises flowing a pretreatment precursor (e.g., Compound X) and carrier gas(es) (e.g., He and/or Ar) into a processing chamber (e.g., a UV-based processing chamber) and exposing surfaces of the substrate to the pretreatment precursor and carrier gas(es) at a processing chamber temperature between 10° C. to 500° C. for a duration between 30 seconds and 6 minutes. The deposition operation comprises gapfilling the trenches with gapfill material (e.g., an oxide film), and flowing carrier gas(es) (e.g., He and/or Ar) and processing gases (e.g., TSA, NH₃, O₂, and H₂) into a processing chamber (e.g., a UV-based processing chamber) containing the substrate at the pressure of less than 1 Torr, such as 0.5 Torr, and a temperature less than 100° C., such as 80° C., for a duration less than 1 minute. The curing operation comprises curing the deposited gapfill material and flowing a curing precursor (e.g., O₃) into the processing chamber at a temperature of less than 100° C., such as 50° C., for a duration of less than 10 mins, such as about 6 mins, at a pressure of less than 100 Torr, such as 50 Torr.

TABLE 3
Summary of Different Treatments and Trench
Surface Dimensions at a Deposition at 80° C.

| | | TMDS | Compound X |
|---|---|---|---|
| | No Pretreatment | Pretreatment | Pretreatment |
| Treatment | (Trench 304A) | (Trench 304B) | (Trench 304C) |
| Water Contact | 7′ | 79′ | 97′ |
| Angle | | | |
| Bottom height (nm) | 17.1 | 14 | 12.7 |
| Sidewall (nm) | 3.3 | 3.4 | 2 |

As can be determined from a comparison and analysis of Tables 2 and 3, the benefits of the hydrophobic pretreatment of the vertical surfaces of the trench are maintained even when conducting the deposition operation at a higher temperature (e.g., conducted at 65° C. in FIG. 3B, then at 80° C. in FIG. 3C). It can further be determined that the deposition of the pretreatment precursor at higher temperature corresponds with a greater improved bottom thickness (i.e., a thinner trench bottom).

FIG. 3D are images depicting a cross-sectional view of trenches having various pretreatment processes at a lower and higher chamber pressure, according to one or more embodiments. The vertical surfaces of trench 306A were not pretreated, yielding a water contact angle of 7′. The vertical surfaces of trench 306B were pretreated at a higher pressure with Compound X. The vertical surfaces of trench 3060 were pretreated at a lower pressure with Compound X.

An exemplary process for pretreating the vertical surfaces of trench 306B with Compound X comprises a pretreatment operation (e.g., operations 202, 206 of FIG. 2), a deposition operation (e.g., operation 208 of FIG. 2), and soaking operation (e.g., operation 210 of FIG. 2). The pretreatment step comprises flowing a pretreatment precursor (e.g., Compound X) and carrier gas(es) (e.g., He and/or Ar) into a processing chamber (e.g., a UV-based processing chamber) and exposing surfaces of the substrate to the pretreatment precursor and carrier gas(es) at a processing chamber temperature between 10° C. to 500° C. for a duration between 30 seconds and 6 minutes. The deposition operation comprises gapfilling the trenches with gapfill material (e.g., an oxide film), and flowing carrier gas (e.g., He or Ar) and processing gases (e.g., TSA, NH₃, O₂, and/or H₂) into a processing chamber (e.g., a UV-based processing chamber) containing the substrate at a pressure of less than or equal to 6 Torr, a temperature less than or equal to 200° C., for a duration of less than or equal to 1 minute, such as 15 seconds. The soaking operation comprises soaking the gapfill material in a soaking precursor (e.g., O₃) in a processing chamber at a temperature of less than 100° C., such as 50° C., for a duration of less than 10 mins, such as about 6 mins, at a pressure of less than 100 Torr, such as 50 Torr.

An exemplary process for pretreating the vertical surfaces of trench 306C with Compound X comprises a pretreatment operation (e.g., operations 202, 206 of FIG. 2), a deposition operation (e.g., operation 208 of FIG. 2), and soaking operation (e.g., operation 210 of FIG. 2). The pretreatment step comprises flowing a pretreatment precursor (e.g., Compound X) and carrier gas(es) (e.g., He and/or Ar) into a processing chamber (e.g., a UV-based processing chamber) and exposing surfaces of the substrate to the pretreatment precursor and carrier gas(es) at a processing chamber temperature between 10° C. to 500° C. for a duration between 30 seconds and 6 minutes. The deposition operation comprises gapfilling the trenches with gapfill material (e.g., an oxide film), and flowing carrier gas (e.g., He and/or Ar) and processing gases (e.g., TSA, NH₃, O₂, and/or H₂) into a processing chamber (e.g., a UV-based processing chamber) containing the substrate at a pressure of less than or equal to 2 Torr, a temperature less than or equal to 200° C., for a duration of less than or equal to 1 minute, such as 15 seconds. The soaking operation comprises soaking the treated substrate in a soaking precursor (e.g., O₃) into the processing chamber at a temperature of less than 100° C., such as 50° C., for a duration of less than 10 mins, such as about 6 mins, at a pressure of less than 100 Torr, such as 50 Torr.

TABLE 4
Summary of Different Treatments and Trench Surface
Dimensions at a higher and lower pressure

| | | Compound X | Compound X |
|---|---|---|---|
| | | Pretreatment at | Pretreatment at |
| | No Pretreatment | High Pressure | Low Pressure |
| Treatment | (Trench 306A) | (Trench 306B) | (Trench 306C) |
| Water Contact | 7′ | 97′ | 97′ |
| Angle | | | |
| Bottom height (nm) | 35 | 24.8 | 18.2 |
| Sidewall (nm) | 2.4 | 1.3 | 1.2 |

As can be determined from analysis of Table 4, the pretreating the vertical surfaces of a trench at a lower pressure (e.g., trench 306C) resulted in a lower bottom height (i.e., thinner trench bottom) when compared to trench 306B which was pretreated at a higher pressure. Thus, pretreating vertical surfaces of a trench at a lower pressure corresponds with an improved bottom thickness (i.e., a thinner trench bottom).

FIG. 3E are images depicting a cross-sectional view of trenches having various pretreatment processes, according to one or more embodiments. The vertical surfaces of trench 308A were not pretreated. The vertical surfaces of trench 308B were pretreated with Compound X and UV. The vertical surfaces of trench 308C were pretreated with Compound X, without UV.

An exemplary process for pretreating the vertical surfaces of trench 308B with Compound X comprises a pretreatment operation (e.g., operations 202, 204, 206 of FIG. 2), a deposition operation (e.g., operation 208 of FIG. 2), and soaking operation (e.g., operation 210 of FIG. 2). The pretreatment step comprises flowing a pretreatment precursor (e.g., Compound X) and carrier gas(es) (e.g., He and/or Ar) into a processing chamber (e.g., a UV-based processing chamber) and exposing surfaces of the substrate to the pretreatment precursor and carrier gas(es) at a processing chamber temperature between 10° C. to 500° C. for a duration between 30 seconds and 6 minutes, and exposing the substrate to UV light at a UV power output of 90%. The deposition operation comprises gapfilling the trenches with gapfill material (e.g., an oxide film), and flowing carrier gas (e.g., He and/or Ar) and processing gases (e.g., TSA, NH₃, O₂, and H₂) into a processing chamber (e.g., a UV-based processing chamber) containing the substrate at a pressure of less than or equal to 2 Torr, a temperature less than or equal to 200° C., for a duration of less than or equal to 1 minute, such as 15 seconds. The soaking operation comprises soaking the treated substrate in a soaking precursor (e.g., O₃) into the processing chamber at a temperature of less than 100° C., such as 50° C., for a duration of less than 10 mins, such as about 6 mins, at a pressure of less than 100 Torr, such as 50 Torr.

An exemplary process for pretreating the vertical surfaces of trench 308C with Compound X comprises a pretreatment operation (e.g., operations 202, 206 of FIG. 2), a deposition operation (e.g., operation 208 of FIG. 2), and soaking operation (e.g., operation 210 of FIG. 2). The pretreatment step comprises flowing a pretreatment precursor (e.g., Compound X) and carrier gas(es) (e.g., He and/or Ar) into a processing chamber (e.g., a UV-based processing chamber) and exposing surfaces of the substrate to the pretreatment precursor and carrier gas(es) at a processing chamber temperature between 10° C. to 500° C. for a duration between 30 seconds and 6 minutes. The deposition operation comprises gapfilling the trenches with gapfill material (e.g., an oxide film), and flowing carrier gas (e.g., He and/or Ar) and processing gases (e.g., TSA, NH₃, O₂, and H₂) into a processing chamber (e.g., a UV-based processing chamber) containing the substrate at a pressure of less than or equal to 2 Torr, a temperature less than or equal to 200° C., for a duration of less than or equal to 1 minute, such as 15 seconds. The soaking operation comprises soaking the treated substrate in a soaking precursor (e.g., O₃) into the processing chamber at a temperature of less than 100° C., such as 50° C., for a duration of less than 10 mins, such as about 6 mins, at a pressure of less than 100 Torr, such as 50 Torr.

TABLE 5
Summary of Different Treatments and Trench Surface Dimensions

| | | Compound X | Compound X |
|---|---|---|---|
| | No Pretreatment | Pretreatment | Pretreatment |
| | and No UV | with UV | without UV |
| Treatment | (Trench 308A) | (Trench 308B) | (Trench 308C) |
| Bottom height (nm) | 13.8 | 8.3 | 10.6 |
| Sidewall (nm) | 4 | 3.2 | 4 |

As can be determined from analysis of Table 5, pretreating the vertical surfaces of a trench with UV resulted in a lesser bottom height (i.e., a thinner trench bottom) when compared to trench 308C which was pretreated without UV. Thus, pretreating vertical surfaces of a trench with UV corresponds with an improved bottom thickness (i.e., a thinner trench bottom).

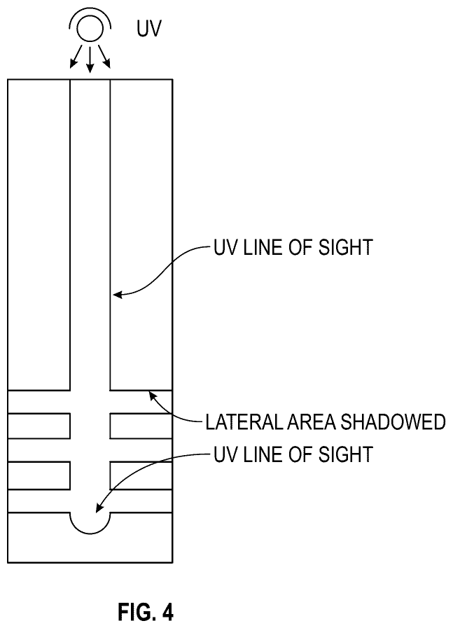

FIG. 4 is a schematic cross-sectional view of a trench, according to one or more embodiments. The process of pretreating surfaces of a trench, so that the vertical surfaces of the trench are made hydrophobic (e.g., via method 200 of FIG. 2), by flowing one or more pretreatment precursors, such as a hydrocarbon compound, Tetramethyldisiloxane (TMDS), DMATMS, or chemical compound (“Compound X”), into a processing chamber with UV light. In such circumstances, the lateral surfaces of the trench are shadowed, while the vertical surfaces of the trench are exposed to the UV line of sight. As a result, the surfaces of the exposed portions (i.e., the vertical trenches) are selectively pretreated to become hydrophobic.

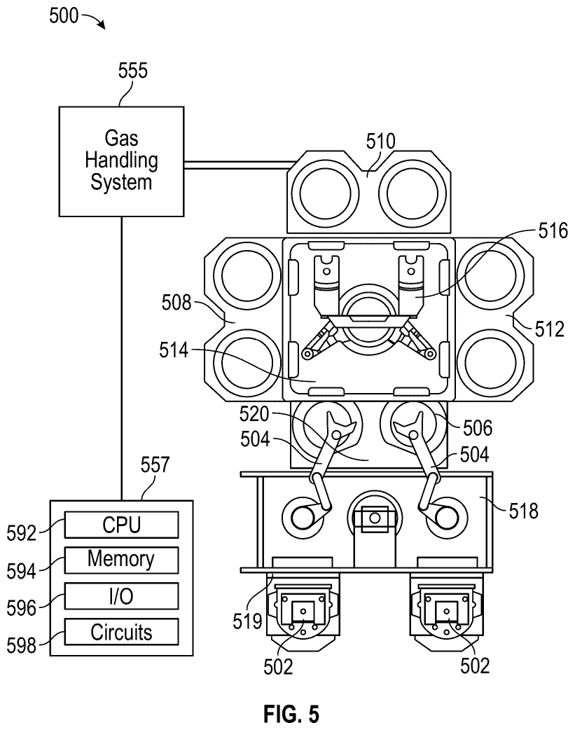

FIG. 5 illustrates a cluster tool 500, according to one or more embodiments. A factory interface 518 is connected to a front of the cluster tool 500. The factory interface 518 includes chambers 502 for loading and unloading on a front 519 of the factory interface 518. The size and shape of the loading chamber and unloading chamber 502 can vary depending on, for example, the substrates being processed in the cluster tool 500. In the embodiment shown, the loading chamber and unloading chamber 502 are sized to hold a wafer cassette with a plurality of wafers positioned within the cassette.

Robots 504 are within the factory interface 518 and can move between the loading and unloading chambers 502. The robots 504 are capable of transferring a wafer from a cassette in the loading chamber 502 through the factory interface 518 to load lock chamber 520. The robots 504 are also capable of transferring a substrate from the load lock chamber 520 through the factory interface 518 to a cassette in the unloading chamber 502. The robot 516 of some embodiments is a multi-arm robot capable of independently moving more than one wafer at a time. The robot 516 is configured to move substrates between the chambers around the transfer chamber 514. Individual wafers are carried upon a substrate transport blade that is located at a distal end of the first robotic mechanism.

A system controller 557 is in communication with the robot 516, and a plurality of processing chambers 508, 510 and 512. The system controller 557 can be any suitable component that can control the processing chambers and robots. For example, the system controller 557 can be a computer including a central processing unit (CPU) 592, memory 594, inputs/outputs 596, suitable circuits 598, and storage. In some embodiments, the system controller 557 has a configuration to control the deposition of chamber gases necessary to perform a pretreatment of substrate surfaces on a substrate.

Processes may generally be stored in the memory of the system controller 557 as a software routine that, when executed by the processor, causes the processing chamber to perform processes of the present disclosure. The software routine may also be stored and/or executed by a second processor (not shown) that is remotely located from the hardware being controlled by the processor. Some or all of the method of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general purpose computer into a specific purpose computer (controller) that controls the chamber operation such that the processes are performed.

In one embodiment which may be combined with other embodiments, a method includes positioning a substrate having a feature formed therein within a processing chamber, the feature comprising a vertical trench and one or more lateral trenches extending from the vertical trench; exposing the substrate to at least one pretreatment precursor to pretreat the substrate, wherein pretreating the substrate increases a hydrophobicity of one or more surfaces of the feature in the substrate; and depositing a gapfill material on the substrate and the feature formed therein to gapfill the vertical trench and the one or more lateral trenches of the feature.

The method further includes exposing the substrate to a UV light when exposing the substrate to the at least one pretreatment precursor. The UV light has a UV power output less than or equal to about 90%. The UV light has a UV radiance of between about 0 and 400 Arbitrary units. The at least one pretreatment precursor includes a hydrocarbon compound, Tetramethyldisiloxane (TMDS), Dimethylamino Trimethylsilane (DMATMS), a chemical compound having a general structure:

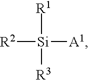

or combinations thereof, wherein R1, R2, and R3 are hydrocarbon functional groups each with a general formula of CₓH_{y} in which x has a range of between 1 and 8 and y has a range of between 1 and 17 and A¹ is a hydrogen atom, chlorine atom, bromine atom, iodine atom, or an amine group. Pretreating the substrate increases a water contact angle of the one or more surfaces of the feature in the substrate. Pretreating the substrate increases a water contact angle of one or more surfaces of the feature in the substrate to greater than about 70°. A chamber pressure of the processing chamber when exposing the substrate to the at least one pretreatment precursor is less than or equal to 2 Torr. A chamber temperature of the processing chamber when exposing the substrate to the at least one pretreatment precursor is 10° C. and 500° C. . . . Depositing the gapfill material on the substrate comprises gapfilling the one or more lateral trenches of the feature prior to gapfilling the vertical trench.

In another embodiment which may be combined with other embodiments, a substrate processing method includes pretreating a substrate containing silicon, wherein the pretreating includes exposing the substrate to at least one pretreatment precursor and a UV light, wherein the at least one pretreatment precursor is one or more of: a hydrocarbon compound, Tetramethyldisiloxane (TMDS), Dimethylamino Trimethylsilane (DMATMS), and a chemical compound having a general structure

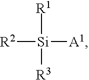

or combinations thereof, wherein R¹, R², and R³ are hydrocarbon functional groups each with a general formula of CₓH_{y} in which x has a range of between 1 and 8 and y has a range of between 1 and 17 and A¹ is a hydrogen atom, chlorine atom, bromine atom, iodine atom, or an amine group; and exposing the substrate to ozone (O₃) after the exposing the substrate to the at least one pretreatment precursor an the UV light, wherein a first surface of the substrate comprises a water contact angle greater than a second surface of the substrate.

The UV light has a UV power output less than or equal to about 90%. The UV light has a UV radiance of between about 0 and 400 Arbitrary units. The substrate is exposed to the at least one pretreatment precursor and UV light for a duration between 30 seconds to 6 minutes. A chamber pressure during the exposing of the substrate is less than or equal to 2 Torr. A chamber temperature when exposing the substrate to the at least one pretreatment precursor is 10° C. and 500° C. The substrate has a feature formed therein, the feature comprising a vertical trench and one or more lateral trenches extending from the vertical trench. Pretreating the substrate increases a hydrophobicity of the first surface of the substrate.

In yet another embodiment which may be combined with other embodiments, a non-transitory computer readable medium includes instructions, that, when executed by a controller of a processing chamber, causes the processing chamber to perform operations includes positioning a substrate within a processing chamber; exposing the substrate to at least one pretreatment precursor to pretreat the substrate, wherein a pretreatment precursor is one or more of: a hydrocarbon compound, Tetramethyldisiloxane (TMDS), Dimethylamino Trimethylsilane (DMATMS), a chemical compound having a general structure:

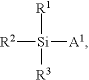

or combinations thereof, wherein R1, R2, and R3 are hydrocarbon functional groups each with a general formula of CₓH_{y} in which x has a range of between 1 and 8 and y has a range of between 1 and 17 and A¹ is a hydrogen atom, chlorine atom, bromine atom, iodine atom, or an amine group; and curing the substrate, a first surface of the substrate having a water contact angle greater than a second surface of the substrate.

The substrate of the previous paragraph has a feature formed therein, the feature comprising a vertical trench and one or more lateral trenches extending from the vertical trench, and pretreating the substrate increases a hydrophobicity of the first surface of the substrate.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A method, comprising:
positioning a substrate having a feature formed therein within a processing chamber, the feature comprising a vertical trench and one or more lateral trenches extending from the vertical trench;
exposing the substrate to at least one pretreatment precursor to pretreat the substrate, wherein pretreating the substrate increases a hydrophobicity of one or more surfaces of the feature in the substrate; and
depositing a gapfill material on the substrate and the feature formed therein to gapfill the vertical trench and the one or more lateral trenches of the feature.

2. The method of claim 1, further comprising exposing the substrate to a UV light when exposing the substrate to the at least one pretreatment precursor.

3. The method of claim 2, wherein the UV light has a UV power output less than or equal to about 90%.

4. The method of claim 2, wherein the UV light has a UV radiance of between about 0 and 400 Arbitrary units.

5. The method of claim 1, wherein the at least one pretreatment precursor is one or more of:
a hydrocarbon compound,
Tetramethyldisiloxane (TMDS),
Dimethylamino Trimethylsilane (DMATMS), and
a chemical compound having a general structure 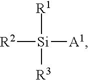
or combinations thereof, wherein R¹, R², and R³ are hydrocarbon functional groups each with a general formula of CₓH_{y} in which x has a range of between 1 and 8 and y has a range of between 1 and 17 and A¹ is a hydrogen atom, chlorine atom, bromine atom, iodine atom, or an amine group.

6. The method of claim 1, wherein pretreating the substrate increases a water contact angle of the one or more surfaces of the feature in the substrate.

7. The method of claim 6, wherein pretreating the substrate increases a water contact angle of one or more surfaces of the feature in the substrate to greater than about 70°.

8. The method of claim 1, wherein a chamber pressure of the processing chamber when exposing the substrate to the at least one pretreatment precursor is less than or equal to 2 Torr.

9. The method of claim 1, wherein a chamber temperature of the processing chamber when exposing the substrate to the at least one pretreatment precursor is between 10° C. and 500° C.

10. The method of claim 1, wherein depositing the gapfill material on the substrate comprises gapfilling the one or more lateral trenches of the feature prior to gapfilling the vertical trench.

11. A substrate processing method, comprising:
pretreating a substrate containing silicon, wherein the pretreating comprises:
exposing the substrate to at least one pretreatment precursor and a UV light, wherein the at least one pretreatment precursor is one or more of:
a hydrocarbon compound,
Tetramethyldisiloxane (TMDS),
Dimethylamino Trimethylsilane (DMATMS), and
a chemical compound having a general structure 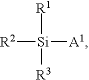
or combinations thereof, wherein R¹, R², and R³ are hydrocarbon functional groups each with a general formula of CₓH_{y} in which x has a range of between 1 and 8 and y has a range of between 1 and 17 and A¹ is a hydrogen atom, chlorine atom, bromine atom, iodine atom, or an amine group; and
exposing the substrate to ozone (O₃) after the exposing the substrate to the at least one pretreatment precursor an the UV light, wherein a first surface of the substrate comprises a water contact angle greater than a second surface of the substrate.

12. The substrate processing method of claim 11, wherein the UV light has a UV power output less than or equal to about 90%.

13. The substrate processing method of claim 11, wherein the UV light has a UV radiance of between about 0 and 400 Arbitrary units.

14. The substrate processing method of claim 11, wherein the substrate is exposed to the at least one pretreatment precursor and UV light for a duration between 30 seconds to 6 minutes.

15. The substrate processing method of claim 14, wherein a chamber pressure during the exposing of the substrate is less than or equal to 2 Torr.

16. The substrate processing method of claim 11, wherein a chamber temperature when exposing the substrate to the at least one pretreatment precursor is 10° C. and 500° C.

17. The substrate processing method of claim 11, wherein the substrate has a feature formed therein, the feature comprising a vertical trench and one or more lateral trenches extending from the vertical trench.

18. The substrate processing method of claim 11, pretreating the substrate increases a hydrophobicity of the first surface of the substrate.

19. A non-transitory computer readable medium including instructions, that, when executed by a controller of a processing chamber, causes the processing chamber to perform operations comprising:
positioning a substrate within a processing chamber;
exposing the substrate to at least one pretreatment precursor to pretreat the substrate, wherein a pretreatment precursor is one or more of:
a hydrocarbon compound,
Tetramethyldisiloxane (TMDS),
Dimethylamino Trimethylsilane (DMATMS), and
a chemical compound having a general structure 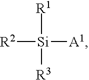
or combinations thereof, wherein R¹, R², and R³ are hydrocarbon functional groups each with a general formula of CₓH_{y} in which x has a range of between 1 and 8 and y has a range of between 1 and 17 and A¹ is a hydrogen atom, chlorine atom, bromine atom, iodine atom, or an amine group; and
curing the substrate, a first surface of the substrate having a water contact angle greater than a second surface of the substrate.

20. The non-transitory computer readable medium of claim 19, wherein the substrate has a feature formed therein, the feature comprising a vertical trench and one or more lateral trenches extending from the vertical trench, and
pretreating the substrate increases a hydrophobicity of the first surface of the substrate.
